(19) United States
(12) Patent Application Publication
(10) Pub. No.: US 2026/0188860 A1
(43) Pub. Date: Jul. 2, 2026

(54) CELLS CONTACT SYSTEM, TEMPERATURE DETECTION METHOD, AND BATTERY MODULE

(71) Applicant: EVE ENERGY CO., LTD., Huizhou (CN)

(72) Inventors: Lei WANG, Huizhou (CN); Yanyan LI, Huizhou (CN)

(73) Assignee: EVE ENERGY CO., LTD., Huizhou (CN)

(21) Appl. No.: 19/548,879

(22) Filed: Feb. 24, 2026

Related U.S. Application Data
(63) Continuation of application No. PCT/CN2024/106130, filed on Jul. 18, 2024.

(30) Foreign Application Priority Data
Aug. 31, 2023 (CN) 202311125261.1

(51) Int. Cl. H01M 50/519; G01R 31/3835; H01M 10/42; H01M 10/48; H01M 50/298; H01M 50/514; H01M 50/569

(52) U.S. Cl. CPC H01M 50/519; G01R 31/3835; H01M 10/425; H01M 10/482; H01M 10/486; H01M 50/298; H01M 50/514; H01M 50/569; H01M 2010/4278

(57) ABSTRACT

A cells contact system for a battery module includes a circuit board configured to be connected with a control board of the battery module. The cells contact system also includes a temperature sensor disposed on the circuit board. The temperature sensor includes a temperature detection surface. The temperature sensor is configured to transmit a temperature signal to the control board through the circuit board. The cells contact system further includes an electrical conductor disposed on the circuit board. The electrical conductor protrudes beyond the temperature detection surface. The electrical conductor is configured to contact a temperature detection portion of the battery module to generate an electrical signal when the temperature detection surface is in close proximity to a surface of the battery module.

### CROSS-REFERENCE TO RELATED APPLICATIONS

This application is a continuation of International Application No. PCT/CN2024/106130, filed on Jul. 18, 2024, which claims priority to Chinese Patent Application No. 202311125261.1, filed on Aug. 31, 2023. The contents of the above-mentioned applications are incorporated herein by reference in their entireties.

### TECHNICAL FIELD

The present disclosure relates to energy storage technologies, and more particularly to a cells contact system, a temperature detection method, and a battery module.

### BACKGROUND

In conventional battery modules, temperature sensors are typically arranged near the surface of an aluminum bar or a cell terminal. To ensure the accuracy of the temperature acquired by the temperature sensor, plastic brackets or structural adhesives are often used to maintain contact.

However, during operation of a battery pack system, it is difficult to verify if the temperature sensor remains in close proximity to the target surface of a battery component, making it challenging to determine if an acquired temperature signal truly reflects the actual temperature of the battery component.

### SUMMARY

Some embodiments of the present disclosure provide a cells contact system for a battery module. The cells contact system includes a circuit board configured to be connected with a control board of the battery module. The cells contact system also includes a temperature sensor disposed on the circuit board. The temperature sensor includes a temperature detection surface. The temperature sensor is configured to transmit a temperature signal to the control board through the circuit board. The cells contact system further includes an electrical conductor disposed on the circuit board. The electrical conductor protrudes beyond the temperature detection surface. The electrical conductor is configured to, when the temperature detection surface is in close proximity to a target surface of the battery module, contact a temperature detection portion of the battery module to generate an electrical signal.

Some embodiments of the present disclosure provide a temperature detection method performed by the above cells contact system. The method includes obtaining the temperature signal from the temperature sensor. In response to detecting the electrical signal on the electrical conductor, the method includes determining that a detected temperature value corresponding to the temperature signal represents a temperature of the battery module.

Some embodiments of the present disclosure provide a battery module. The battery module includes a control board, a plurality of cells each including a target surface and a temperature detection portion, and a cells contact system. The cells contact system includes a circuit board configured to be connected with the control board. The cells contact system also includes a temperature sensor disposed on the circuit board. The temperature sensor includes a temperature detection surface, and the temperature sensor is configured to transmit a temperature signal to the control board through the circuit board. The cells contact system further includes an electrical conductor disposed on the circuit board. The electrical conductor protrudes beyond the temperature detection surface, and the electrical conductor is configured to, when the temperature detection surface of the temperature sensor is in close proximity to the target surface of at least one of the plurality of cells, contact the temperature detection portion of the at least one of the plurality of cells to generate an electrical signal.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the disclosure.

FIG. 1 is a schematic diagram of a structure of an exemplary cells contact system, according to some embodiments of the present disclosure.

FIG. 2 schematically shows a cross-section of the cells contact system taken along line A-A in FIG. 1.

FIG. 3 is an enlarged view of part B in FIG. 2.

FIG. 4 is a schematic block diagram of an exemplary auxiliary determination circuit including electrical conductors, according to some embodiments of the present disclosure.

FIG. 5 is a schematic flowchart of an exemplary temperature detection method, according to some embodiments of the present disclosure.

FIG. 6 is a schematic diagram of a structure of an exemplary battery module, according to some embodiments of the present disclosure.

FIG. 7 is an enlarged view of part C in FIG. 6.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented.

In the description of the present disclosure, it should be noted that unless otherwise clearly defined and limited, the terms “coupled,” “connected,” and “fixed” should be interpreted broadly. For example, the terms may refer to a fixed connection, a detachable connection, or an integral connection; the terms may also refer to a mechanical connection, an electrical connection, a direct connection, an indirect connection through an intermediary, or an interconnection between two elements or interactive relationship between two elements. Those skilled in the art can understand the specific meanings of the above-mentioned terms in the present disclosure according to circumstances.

In the present disclosure, it should he noted that unless otherwise clearly defined and limited, a first feature “on top of” or “under” a second feature may mean that the first feature directly contacts the second feature, or that the first feature contacts the second feature via an additional feature therebetween instead of directly contacting the second feature. Moreover, the first feature “on,” “above,” and “over” the second feature may mean that the first feature is right above or obliquely upward above the second feature or mean that the first feature has a horizontal height higher than that of the second feature. The first feature “underneath,” “below,” and “beneath” the second feature may mean that the first feature is right below or obliquely downward below the second feature or mean that that the horizontal height of the first feature is lower than that of the second feature.

In the description of the present disclosure, it should be understood that orientations or position relationships indicated by the terms “upper,” “lower,” “left,” “right,” “front,” “rear,” or the like are based on orientations or position relationships illustrated in the drawings. The terms are used to facilitate and simplify the description of the present disclosure, rather than indicate or imply that the devices or elements referred to herein are required to have specific orientations or be constructed or operated in the specific orientations. Accordingly, the terms should not be construed as limiting the present disclosure. In addition, the term “first,” “second,” or the like are used to distinguish in the description and have no special meaning.

With the rapid development of electric vehicles, battery management systems have also experienced significant advancements as core components of the electric vehicles. A cells contact system (CCS) is an important component for acquiring internal state parameters of a battery module. A temperature parameter is a key parameter requiring rigorous monitoring in battery modules. In the related art, after a temperature sensor is assembled to the battery module, it is difficult to verify whether the temperature sensor is in close proximity to a target surface of a component of the battery module due to the assembly precision and operational factors, and therefore it is difficult to verify the authenticity of temperature data measured from inside the battery module.

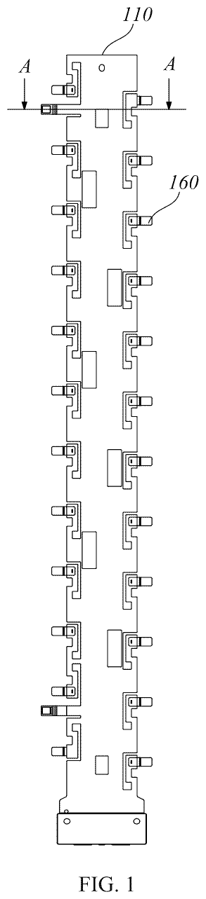

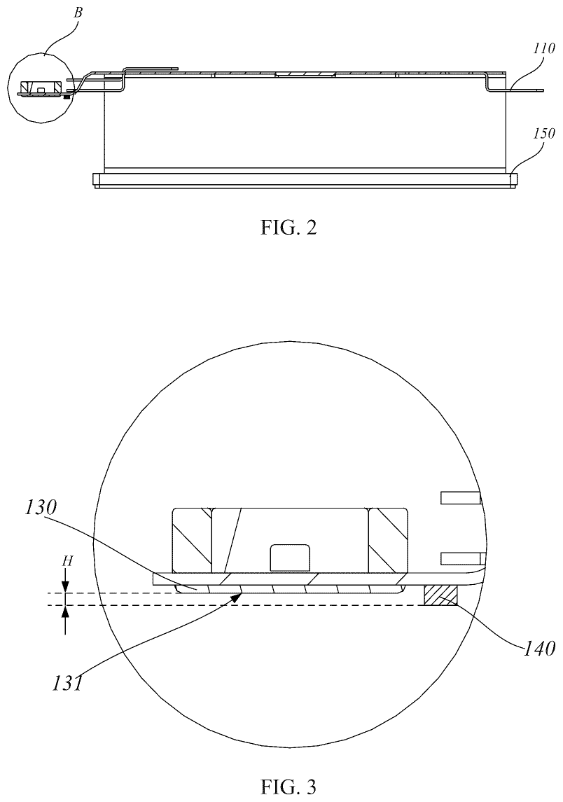

An embodiment of the present disclosure provides a cells contact system for a battery module. Referring to FIGS. 1 to 4, an electrical conductor 140 is provided in the cells contact system, and the electrical conductor 140 can generate an electrical signal when it contacts a temperature detection portion 20 of the battery module. A control board 120 of the battery module may determine, by using the electrical signal, that a detected temperature value corresponding to a temperature signal acquired by a temperature sensor 130 represents the temperature of the battery module.

In some embodiments, referring to FIGS. 1 to 4, the cells contact system includes a circuit board 110, the temperature sensor 130, and the electrical conductor 140.

As shown in the embodiment of FIGS. 1 to 4, the circuit board 110 is configured to connect with the control board 120 of the battery module. The temperature sensor 130 is disposed on the circuit board 110. The temperature sensor 130 has a temperature detection surface 131. The temperature sensor 130 is configured to acquire the temperature signal and transmit (e.g., upload) the temperature signal to the control board 120 through the circuit board 110.

As shown in the embodiment of FIGS. 1 to 4, the electrical conductor 140 is disposed on the circuit board 110 and protrudes beyond the temperature detection surface 131. The electrical conductor 140 is configured to contact the temperature detection portion 20 (FIG. 7) of the battery module to generate the electrical signal when the temperature detection surface 131 is in close proximity to (or approaches) a target surface (e.g., a surface the temperature of which is to be detected) of the battery module. The electrical signal can then be transmitted through the circuit board 110 to the control board 120.

In an embodiment of the present disclosure, the electrical conductor 140 is provided on the circuit board 110. The electrical conductor 140 protrudes beyond the temperature detection surface 131 of the temperature sensor 130. During assembly of the battery module for acquiring the temperature of the battery module, the electrical conductor 140 is configured to be in contact with the temperature detection portion 20, and at this time, the temperature detection surface 131 is considered to be in close proximity to the temperature detection portion 20. When the electrical conductor 140 contacts the temperature detection portion 20, the electrical signal is generated. Under the condition that the control board 120 detects the electrical signal, it is determined that the detected temperature value corresponding to the temperature signal represents (e.g., reflects) the actual temperature of the battery module. However, due to assembly tolerances or operational factors, the electrical conductor 140 may be disconnected from the temperature detection portion 20, in which case the temperature detection surface 131 is considered to be away from the temperature detection portion 20. When the electrical conductor 140 is disconnected from the temperature detection unit 20, the electrical signal disappears, and the control board 120 cannot detect the electrical signal. The probability that the detected temperature value corresponding to the temperature signal deviates from the actual temperature of the battery module increases. Therefore, in the present embodiment of the present disclosure, the authenticity of the detected temperature value may be effectively determined, thereby improving the reliability of the battery pipeline system and improving the safety of the battery module.

In an embodiment, the temperature sensor 130 and the electrical conductor 140 are used in pairs. For example, the temperature sensor 130 acquires the temperature of one of the cells 10 of the battery module, and the electrical conductor 140 is arranged to contact the temperature detection portion 20 of the one of the cells 10.

In an example, the target surface to which the temperature detection surface 131 is configured to be in close proximity may be a surface of the cell 10, or may be a surface of the bar 21, depending on particular applications.

In some embodiments, the temperature detection portion 20 to be contacted by the electrical conductor 140 may be connected to an input terminal (or an output terminal) of the control board 120 via a harness, and the electrical conductor 140 is connected to an output terminal (or an input terminal) of the control board 120 via the circuit board 110. After the electrical conductor 140 contacts the temperature detection portion 20, an electric circuit is formed, allowing the control board 120 to detect the electrical signal. When the electrical conductor 140 is disconnected from the temperature detection portion 20, the electric circuit breaks, and the control board 120 cannot detect the electrical signal.

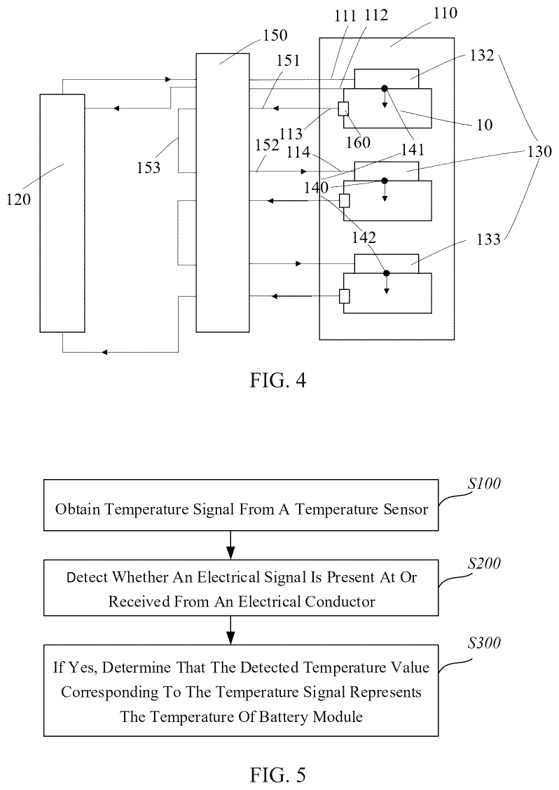

In some embodiments, the electrical conductor 140 forms a circuit connected to the control board 120 by using a portion of a temperature acquisition circuit. Referring to FIG. 4, the circuit board 110 is provided with a first temperature acquisition circuit 111 and a second temperature acquisition circuit 112. The first temperature acquisition circuit 111 is connected to the positive electrode of the temperature sensor 130, and the second temperature acquisition circuit 112 is connected to the negative electrode of the temperature sensor 130. The temperature signal acquired by the temperature sensor 130 is transmitted to the control board 120 through the first temperature acquisition circuit 111 and the second temperature acquisition circuit 112. In an embodiment, the electrical conductor 140 is disposed in any of the first temperature acquisition circuit 111 or the second temperature acquisition circuit 112. That is, the electric circuit for transmitting the electrical signal from the electrical conductor 140 may reuse any one of the first temperature acquisition circuit 111 and the second temperature acquisition circuit 112 to reduce the manufacturing process of the circuit board 110.

In an example, the electrical conductor 140 may be a tin block formed by tin plating at the end of the first temperature acquisition circuit 111 or the second temperature acquisition circuit 112, and the tin block protrudes beyond a temperature detection plane. For example, as shown in FIG. 4, the electrical conductor 140 may be a tin block formed by tin plating on the end of the second temperature acquisition circuit 112. In other example, the electrical conductor 140 may be tin block formed by tin plating on the end of the first temperature acquisition circuit 111. In some embodiments, the electrical conductor 140 may include a conductive metal, such as copper, aluminum, or the like, in addition to a tin block.

In some embodiments, one of the first temperature acquisition circuit 111 and the second temperature acquisition circuit 112 is connected to an input terminal (or output terminal) of the control board 120, and the other one is connected to a temperature acquisition terminal of the control board 120. The temperature detection portion 20 to be contacted by the electrical conductor 140 may be connected to the output terminal (or input terminal) of the control board 120 via the harness.

In some embodiments, the electrical conductor 140 forms a circuit connected to the control panel 120 via a portion of the temperature acquisition circuit and a portion of a voltage acquisition circuit 113. The voltage acquisition circuit 113 is a circuit on the circuit board 110 that transmits a voltage acquired by the cells contact system to the control board 120. The cells contact system may include a voltage acquisition sheet 160 disposed on the circuit board 110. The circuit board 110 is further provided with the voltage acquisition circuit 113 connected to the voltage acquisition sheet 160. The voltage acquisition sheet 160 is configured to contact the temperature detection portion 20. In an example, when the voltage acquisition sheet 160 contacts the temperature detection portion 20, under the condition that the electrical conductor 140 also contacts the temperature detection portion 20 at the same time, the electrical conductor 140 is electrically connected to the voltage acquisition sheet 160 through the temperature detection portion 20, so that the electrical conductor 140 is electrically connected to the voltage acquisition circuit 113, and the electrical conductor 140 generates the electrical signal. That is, the circuit between the electrical conductor 140 and the control board 120 includes part of the temperature acquisition circuit and part of the voltage acquisition circuit 113. With this configuration, the manufacturing process of the circuit board 110 may be reduced, and the harness may be reduced, thereby facilitating cost reduction.

In an example, the battery module may include a plurality of cells 10, and the temperature sensor 130 is provided to include at least two temperature sensors 130. Accordingly, the electrical conductor 140 is also provided to include at least two electrical conductors 140. The electrical conductor 140 includes at least two electrical conductors 140, and each of the at least two temperature sensors 130 is disposed in correspondence with a corresponding one of the at least two electrical conductors 140. After the cells contact system is assembled into a battery module, a temperature sensor 130 and an electrical conductor 140 are arranged in a one-to-one correspondence. Each temperature sensor 130 performs temperature detection for a corresponding one of the cells 10, and the electrical conductor 140 in a one-to-one correspondence with each temperature sensor 130 is configured to contact the corresponding one of the cells 10. During operation, a temperature sensor 130 can be used to detect the temperature of a cell 10 together with its corresponding electrical conductor 140 that is configured to contact the temperature detection portion 20 of the cell 10 to indicate the authenticity of the detected temperature.

In some embodiment, the cells contact system further includes a module connector 150. The circuit board 110 is also provided with at least one auxiliary circuit 114. For two adjacent electrical conductors 140, one of the two adjacent electrical conductors 140 is connected to the auxiliary circuit 114 through its corresponding temperature sensor 130, the auxiliary circuit 114 is connected to the voltage acquisition circuit 113, to which the other one of two adjacent electrical conductors 140 is connected, through the module connector 150. In an embodiment, the electrical conductors 140 are connected in series by using the module connector 150 and the voltage acquisition circuit 113. In this embodiment, when one of the electrical conductors 140 is disconnected from the corresponding temperature detection portion 20, the control board 120 cannot detect the electrical signal. With this configuration, the control board 120 can effectively determine whether or not all the temperature sensors 130 effectively are in close proximity to the target surfaces, while the number of external harnesses may be reduced.

In some embodiments, each of the electrical conductors 140 may be connected to the control panel 120 through its corresponding voltage acquisition circuit 113. In comparison with the above-described embodiment, when one of the electrical conductors 140 is disconnected from the temperature detection portion 20, the control board 120 may detect an electrical signal of the other one of the electrical conductors 140. In this configuration, the interface of the control board 120 and the external harness need to be added.

In some embodiment, the temperature sensor 130 includes a head temperature sensor 132 and a tail temperature sensor 133, and the electrical conductor 140 includes a head electrical conductor 141 and a tail electrical conductor 142. The head temperature sensor 132 is provided in correspondence with the head electrical conductor 141, and the tail temperature sensor 133 is provided in correspondence with the tail electrical conductor 142. In an example, the temperature detection surface 131 of the head temperature sensor 132 is in close proximity to the target surface of a first cell, and the head electrical conductor 141 is configured to contact the temperature detection portion 20 of the first cell. The temperature detection surface 131 of the tail temperature sensor 133 is in close proximity to the target surface of a second cell, and the tail electrical conductor 142 is configured to contact the temperature detection portion 20 of the second cell. The head temperature sensor 132 is connected to the output interface (or output terminal) of the control board 120 through the first temperature acquisition circuit 111 and the module connector 150, and the tail electrical conductor 142 is connected to the input interface (or input terminal) of the control board 120 through its corresponding voltage acquisition circuit 113 and the module connector 150. With this arrangement, the head circuit and the tail circuit through which the electrical signal from the electrical conductor 140 is transmitted is connected to the output interface/terminal and the input interface/terminal of the control board 120, respectively, so that the number of interfaces/terminals of the control board 120 may be reduced.

In some embodiments, for example as shown in FIG. 4, the cells contact system further includes a first harness 151 and a second harness 152. The module connector 150 includes an internal harness 153. The first harness 151 is connected to the second harness 152 through the internal harness 153. The voltage acquisition circuit 113 is connected to the first harness 151. The auxiliary circuit 114 is connected to the second harness 152. That is, a portion of the circuit, outside the circuit board 110, for transmitting the electrical signal from the electrical conductor 140 includes the first harness 151, the second harness 152, and the internal harness 153.

As shown in FIG. 4, the temperature sensor includes the head temperature sensor 132, the tail temperature sensor 133, and an intermediate temperature sensor. The head temperature sensor 132 is connected to the output terminal of the control board 120 by using the first temperature acquisition circuit 111 and the module connector 150. The head electrical conductor 141 corresponding to the head temperature sensor 132 is disposed in the second temperature acquisition circuit 112 for the head temperature sensor 132. The circuit board 110 is further provided with a head voltage acquisition sheet and the voltage acquisition circuit 113 corresponding to the head voltage acquisition sheet, and the head voltage acquisition sheet is configured to detect the cell corresponding to the head temperature sensor 132. The voltage acquisition circuit 113 corresponding to the head voltage acquisition sheet is connected to the first temperature acquisition circuit 111 of the intermediate temperature sensor through the corresponding first harness 151, the internal harness 153, the second harness 152, and the auxiliary circuit 114, and the intermediate electrical conductor corresponding to the intermediate temperature sensor is provided on the second temperature acquisition circuit 112 for the intermediate temperature sensor. The circuit board 110 is further provided with an intermediate voltage acquisition sheet and the voltage acquisition circuit 113 corresponding to the intermediate voltage acquisition sheet, and the intermediate voltage acquisition sheet is configured to detect the cell 10 corresponding to the intermediate temperature sensor. The voltage acquisition circuit 113 corresponding to the intermediate voltage acquisition sheet is connected to the first temperature acquisition circuit 111 of the tail temperature sensor 133 through the corresponding first harness 151, the internal harness 153, the second harness 152, and the auxiliary circuit 114, and the tail electrical conductor 142 corresponding to the tail temperature sensor 133 is provided on the second temperature acquisition circuit 112 of the tail temperature sensor 133. The circuit board 110 is further provided with a tail voltage acquisition sheet and a voltage acquisition circuit 113 corresponding to the tail voltage acquisition sheet, the tail voltage acquisition sheet is configured to detect the cell 10 corresponding to the tail temperature sensor 133. The voltage acquisition circuit 113 corresponding to the tail voltage acquisition sheet is connected to the input terminal of the control board 120 through the module connector 150.

In this embodiment, when the head electrical conductor 141, the middle electrical conductor and the tail electrical conductor 142 contact the temperature detection portions 20 of their respective cells 10 at the same time, the circuit is configured to assist in determining that the temperature detection is turned on, and the control board 120 may detect the electrical signal.

In the above embodiment, as shown in FIG. 3, the electrical conductor 140 protrudes beyond the temperature detection surface 131 by a distance H, and the value of the distance H may satisfy: 0<H≤0.5 mm. In the embodiment, the distance by which the electrical conductor 140 protrudes beyond the temperature detection surface 131 should not be too great, and the distance is limited to less than or equal to 0.5 mm, so as to ensure that an effective distance between the temperature detection surface 131 and the target surface is maintained. In an example, the value of the distance H satisfies: 0.3 mm≤H≤0.5 mm.

In some embodiments, the temperature sensor 130 is packaged onto the circuit board 110. In an embodiment, the temperature sensor 130 is disposed at the end of the temperature acquisition circuit of the circuit board 110 in the form of a surface-mount technology (SMT) package. There is an NTC thermistor within the temperature sensor 130.

An embodiment of the present disclosure further provides a temperature detection method for the cells contact system as described above. As shown in FIG. 5, the method includes Steps S100, S200, and S300.

At Step S100, a temperature signal from the temperature sensor 130 is obtained.

At Step S200, it is detected whether an electrical signal is present at or received from the electrical conductor 140.

At Step S300, if Yes, it is determined that the detected temperature value corresponding to the temperature signal represents the temperature of the battery module.

In the temperature detection method according to an embodiment of the present disclosure, by detecting whether the electrical signal is present at or received from the electrical conductor 140, it is determined whether the temperature detection surface 131 is in close proximity to the target surface, and then it is determined whether the detected temperature value corresponding to the temperature signal represents or reflects the temperature of the battery module, so that the reliability of the detected temperature value of the battery module may be effectively improved. When the electrical signal is present or received, the temperature detection surface 131 is in close proximity to the target surface of the battery module, and then it is determined that the detected temperature value corresponding to the temperature signal represents or reflects the temperature of the battery module.

In an embodiment, as shown in FIG. 5, Step S100 may be performed before Step S200. In some embodiments, Step S100 may be performed after Step S200. In some embodiments, Step S100 and Step S200 may be performed synchronously.

When no electrical signal is present or received, the temperature detection surface 131 is considered away from the target surface of the battery module, and then it is determined that the detected temperature value corresponding to the temperature signal may be different from the actual temperature of the battery module. In this case, a mark may be made to indicate that there is a deviation in the detected temperature value.

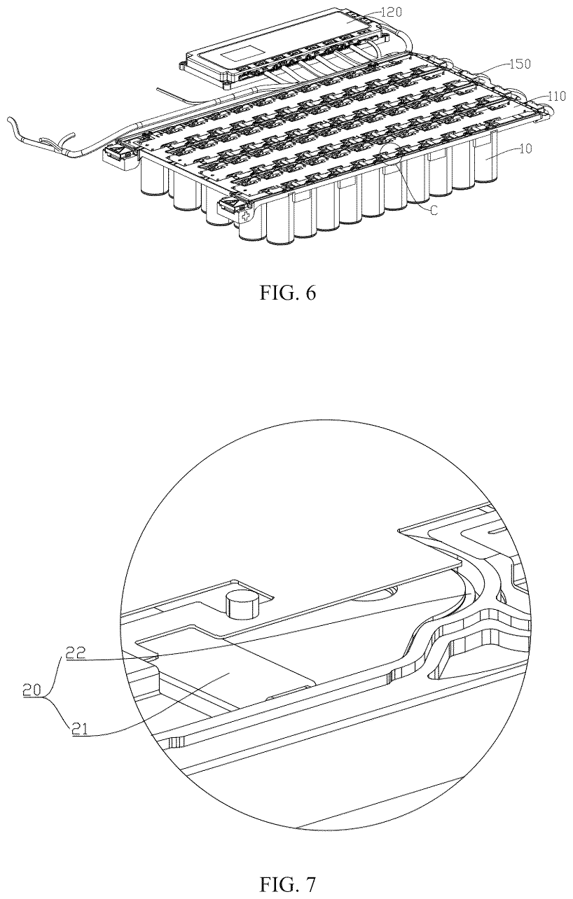

An embodiment of the present disclosure provides a battery module. As shown in FIGS. 6 and 7, the battery module includes a plurality of cells 10 each including a temperature detection portion 20, and a cells contact system. In some embodiments, the cells contact system may be implemented according to any of the foregoing embodiments. The temperature detection surface 131 of the temperature sensor 130 is in close proximity to the temperature detection portion 20 of at least one of the plurality of cells 10, and the electrical conductor 140 contacts the temperature detection portion 20 of the at least one cell 10 to which the temperature sensor 130 is in close proximity.

In this battery module, whether the detected temperature value corresponding to the temperature signal detected by the temperature sensor 130 is accurate or not is determined by detecting the electrical signal from the electrical conductor 140, so that the reliability of the temperature detection may be improved, and the safety of the battery module may be improved.

In some embodiments, the battery module further includes a thermal conductive adhesive, and the temperature detection portion 20 includes a terminal 22 or a bar 21, and the temperature detection surface 131 is connected to the terminal 22 or the bar 21 through the thermal conductive adhesive. In this embodiment, the temperature detection surface 131 is fixed to the bar 21 or the terminal 22 by the thermal conductive adhesive, and the temperature detection is performed by heat conduction.

Some embodiments of the present disclosure have been described in detail above. The description of the above embodiments merely aims to help to understand the present disclosure. Many modifications or equivalent substitutions with respect to the embodiments may be obvious to those of ordinary skill in the art based on the present disclosure. Thus, these modifications or equivalent substitutions shall fall within the scope of the present disclosure.

1. A cells contact system for a battery module, comprising:
a circuit board configured to be connected with a control board of the battery module;
a temperature sensor disposed on the circuit board, wherein the temperature sensor comprises a temperature detection surface, and the temperature sensor is configured to transmit a temperature signal to the control board through the circuit board; and
an electrical conductor disposed on the circuit board, wherein the electrical conductor protrudes beyond the temperature detection surface, and the electrical conductor is configured to, when the temperature detection surface is in close proximity to a target surface of the battery module, contact a temperature detection portion of the battery module to generate an electrical signal.

2. The cells contact system of claim 1, further comprising:
a first temperature acquisition circuit and a second temperature acquisition circuit disposed on the circuit board,
wherein:
the first temperature acquisition circuit is connected to a positive electrode of the temperature sensor, and the second temperature acquisition circuit is connected to a negative electrode of the temperature sensor; and
the electrical conductor is disposed in the first temperature acquisition circuit or the second temperature acquisition circuit.

3. The cells contact system of claim 2, further comprising:
a voltage acquisition sheet disposed on the circuit board,
wherein:
a voltage acquisition circuit is disposed on the circuit board and connected with the voltage acquisition sheet; and
the voltage acquisition sheet is configured to electrically connect the electrical conductor and the voltage acquisition circuit when the voltage acquisition sheet contacts the temperature detection portion.

4. The cells contact system of claim 3, comprising:
a plurality of temperature sensors;
a plurality of electrical conductors respectively corresponding to the plurality of temperature sensors;
a module connector; and
an auxiliary circuit disposed on the circuit board;
wherein:
a first electrical conductors of the plurality of electrical conductors is connected to the auxiliary circuit through a first temperature sensor of the plurality of the temperature sensors corresponding to the first electrical conductor; and
the auxiliary circuit is connected, through the module connector, to the voltage acquisition circuit, which is to be electrically connected with a second electrical conductor of the plurality of electrical conductors that is adjacent to the first electrical conductor.

5. The cells contact system of claim 4, wherein:
the plurality of temperature sensors comprise a head temperature sensor and a tail temperature sensor; and
the plurality of electrical conductors comprise a head electrical conductor and a tail electrical conductor respectively corresponding to the head temperature sensor and the tail temperature sensor;
wherein the head temperature sensor is connected to an output interface of the control board through the first temperature acquisition circuit and the module connector, and the tail electrical conductor is connected to an input interface of the control board through the voltage acquisition circuit corresponding to the tail electrical conductor and the module connector.

6. The cells contact system of claim 5, further comprising a first harness and a second harness,
wherein:
the module connector comprises an internal harness;
the first harness is connected to the second harness through the internal harness; and
the voltage acquisition circuit is connected with the first harness, and the auxiliary circuit is connected with the second harness.

7. The cells contact system of claim 4, further comprising a first harness and a second harness,
wherein:
the module connector comprises an internal harness;
the first harness is connected to the second harness through the internal harness; and
the voltage acquisition circuit is connected with the first harness, and the auxiliary circuit is connected with the second harness.

8. The cells contact system of claim 1, wherein the electrical conductor is configured to protrude beyond the temperature detection surface by a distance H, and 0<H≤0.5 mm.

9. A temperature detection method performed by the cells contact system of claim 1, the temperature detection method comprising:
obtaining the temperature signal from the temperature sensor; and
in response to detecting the electrical signal on the electrical conductor, determining that a detected temperature value corresponding to the temperature signal represents a temperature of the battery module.

10. A battery module comprising:
a control board;
a plurality of cells each comprising a target surface and a temperature detection portion; and
a cells contact system, comprising:
a circuit board configured to be connected with the control board;
a temperature sensor disposed on the circuit board, wherein the temperature sensor comprises a temperature detection surface, and the temperature sensor is configured to transmit a temperature signal to the control board through the circuit board; and
an electrical conductor disposed on the circuit board, wherein the electrical conductor protrudes beyond the temperature detection surface, and the electrical conductor is configured to, when the temperature detection surface of the temperature sensor is in close proximity to the target surface of at least one of the plurality of cells, contact the temperature detection portion of the at least one of the plurality of cells to generate an electrical signal.

11. The battery module of claim 10, further comprising a thermal conductive adhesive,
wherein the temperature detection portion of the at least one of the plurality of cells comprises a terminal or a bar, and the temperature detection surface of the temperature sensor is connected to the terminal or the bar of the temperature detection portion of the at least one of the plurality of cells through the thermal conductive adhesive.

12. The battery module of claim 10, further comprising:
a first temperature acquisition circuit and a second temperature acquisition circuit disposed on the circuit board,
wherein:
the first temperature acquisition circuit is connected to a positive electrode of the temperature sensor, and the second temperature acquisition circuit is connected to a negative electrode of the temperature sensor; and
the electrical conductor is disposed in the first temperature acquisition circuit or the second temperature acquisition circuit.

13. The battery module of claim 12, wherein the cells contact system further comprises a voltage acquisition sheet disposed on the circuit board,
wherein:
a voltage acquisition circuit is disposed on the circuit board and connected with the voltage acquisition sheet; and
the voltage acquisition sheet is configured to electrically connect the electrical conductor and the voltage acquisition circuit when the voltage acquisition sheet contacts the temperature detection portion.

14. The battery module of claim 13, wherein the cells contact system comprises:
a plurality of temperature sensors;
a plurality of electrical conductors respectively corresponding to the plurality of temperature sensors;
a module connector; and
an auxiliary circuit disposed on the circuit board;
wherein:
a first electrical conductors of the plurality of electrical conductors is connected to the auxiliary circuit through a first temperature sensor of the plurality of the temperature sensors corresponding to the first electrical conductor; and
the auxiliary circuit is connected, through the module connector, to the voltage acquisition circuit, which is to be electrically connected with a second electrical conductor of the plurality of electrical conductors that is adjacent to the first electrical conductor.

15. The battery module of claim 14, wherein:
the plurality of temperature sensors comprise a head temperature sensor and a tail temperature sensor; and
the plurality of electrical conductors comprise a head electrical conductor and a tail electrical conductor respectively corresponding to the head temperature sensor and the tail temperature sensor;
wherein the head temperature sensor is connected to an output interface of the control board through the first temperature acquisition circuit and the module connector, and the tail electrical conductor is connected to an input interface of the control board through the voltage acquisition circuit corresponding to the tail electrical conductor and the module connector.

16. The battery module of claim 15, wherein:
the cells contact system further comprises a first harness and a second harness;
the module connector comprises an internal harness;
the first harness is connected to the second harness through the internal harness; and
the voltage acquisition circuit is connected with the first harness, and the auxiliary circuit is connected with the second harness.

17. The battery module of claim 14, wherein:
the cells contact system further comprises a first harness and a second harness;
the module connector comprises an internal harness;
the first harness is connected to the second harness through the internal harness; and
the voltage acquisition circuit is connected with the first harness, and the auxiliary circuit is connected with the second harness.

18. The battery module of claim 10, wherein the electrical conductor is configured to protrude beyond the temperature detection surface by a distance H, and 0<H≤0.5 mm.
